(19) United States
(12) Patent Application Publication
(10) Pub. No.: US 2005/0220187 A1
(43) Pub. Date: Oct. 6, 2005

(54) Demodulator for pulse-position modulated signals, demodulation method and signal receiver equipped with same

(75) Inventors: Nicolas Delorme, Grenoble (FR); Dominique Morche, Meylan (FR)

Correspondence Address: Robert E Krebs;Thelen Reid & Priest, PO Box 640640, San Jose, CA, 95164-0640, US

(73) Assignee: Commissariat A L'Energie Atomique, Paris (FR)

(21) Appl. No.: 10/515,107

(22) PCT Filed: May 20, 2003
(86) PCT No.: PCT/FR03/01517

§ 371 Date: Nov. 19, 2004

(30) Foreign Application Priority Data
May 22, 2002 (FR) 02/06217

(51) Int. Cl. H03K 7/04

(52) U.S. Cl. 375/239

(57) ABSTRACT

The present invention relates to a pulse-position modulated signal demodulator comprising a correlator. In accordance with the invention, the correlator is an auto-correlator (150, 152, 154, 160) provided with means (150, 152) for generating a decode signal from a pulse-position modulated receive signal.

### TECHNICAL FIELD

The present invention relates to a pulse-position modulated signal demodulator, and a receiver fitted with such a demodulator. It also relates to a corresponding demodulation process.

Data transmission using a pulse-position modulated signal comprises transmission of a carrier signal with pulses of very short duration and a very low duty factor. The pulses received are analogue pulses. Depending on the applications, this received signal may then be processed either in an analogue way, or be digitised, sampled, etc.

Pulses are generally less than one nanosecond in duration and have a duty factor below 1%. The mean time interval separating two pulses is about 100 ns, which equates to a frequency of 10 MHz. The information carried by the signal is encoded by the position, in other words the time of occurrence of the pulse. More exactly, the information is encoded in the form of slight time lags δ, which either do or do not affect the pulses. In still other words, the information transmitted is encoded by the fact that some pulses are sent slightly ahead of time or behind time relative to their moment of normal occurrence.

The bandwidth of pulse-position modulated signals is very wide, about 1 to 5 GHz. Pulse-position modulated signals are therefore known by the name “UWB (Ultra-Wide Bandwidth) signals”.

The invention finds applications in the field of signal transmission and particularly in the transmission of signals by radio microwaves.

### THE PRIOR ART

A description of the prior art is given below with reference to the appended FIG. 1. This may be complemented by the document (1) the references for which are set out at the end of the description.

FIG. 1 shows in a basic way a pulse-position modulated signal receiver. It comprises an amplifier 10 connected to an aerial 12. After amplification, the receive signal r(t) is directed towards a first input 22 of a correlator 20. A second input 24 of the correlator receives a decode signal v(t) which is used to determine the time positions of the receive signal pulses.

The correlator carries out an inter-correlation between the receive signal and the decode signal. It is combined with a baseband processor unit 26 to finally deliver demodulated data to an output S. The data delivered to the output corresponds to that initially encoded in the pulse-position modulated signal r(t).

The decode signal v(t) is supplied by a pulse generator 30 run by a clock 32. A synchronisation unit 34, connected to the processor unit 26 is provided to synchronise the decode signal.

The device according to FIG. 1 poses a certain number of problems. These essentially relate to the generation of a decode signal and the synchronisation of the signal, run by a local clock, with the receive signal.

Another difficulty is related to a sensitivity of the receiver to perturbing signals from competing transmitters, and to noise.

### DISCLOSURE OF THE INVENTION

The purpose of the invention is to propose a signal demodulator and receiver that does not have the difficulties mentioned above.

Another purpose is to propose a simplified demodulator and receiver, that does not contain a local clock, and which does not require a decode signal generated from a local clock to be synchronised with the receive signal.

Another purpose is to propose a demodulator and receiver that are insensitive to noise and insensitive to competing transmitter signals.

Yet another purpose is to propose inexpensive devices comprising a small number of components and with low electrical consumption.

Yet another purpose of the invention is to propose a demodulation process that corresponds to the devices.

To fulfil these purposes, the subject matter of the invention is more exactly a pulse-position modulated signal demodulator, comprising a correlator. In accordance with the invention, the correlator is an auto-correlator provided with means for generating a decode signal from a pulse-position modulated receive signal. By means of the characteristics of the invention, the same receive signal is used as a signal carrying the encoded information and as a source to generate a decode signal (demodulation). In fact since the same signal is involved, the problems of synchronisation with a local clock are eliminated. A local reference clock is otherwise unnecessary.

According to one embodiment of the invention, the auto-correlator comprises a first delay unit for forming a first delayed receive signal and a multiplier for multiplying the first delayed receive signal by the decode signal. The first delayed receive signal is assigned a delay substantially equal to a mean pulse repetition time. The mean pulse repetition time, denoted Δ in the remainder of the text, corresponds in fact to a mean duration separating two successive pulses. A repetition time is considered mean in so far as it can be assigned the delay or advance δ of the individual pulses. However it is appropriate to keep in mind that the duration δ is small considering Δ.

Thanks to the first delay unit, correlation takes place, in a way, between the receive signal and the delayed receive signal. To retain good synchronisation between the delayed pulses and the non-delayed pulses, the demodulator may comprise a delay-locked loop connected between the correlator output and a corrective input of the first delay unit. The delay-locked loop may be connected to the correlator output by means of a low-pass filter. The function of this low-pass filter and the operation of the loop are described below.

In another embodiment of the device, particularly insensitive to interfering signals or noise, the means for generating a decode signal are able to provide a decode signal and may comprise a second delay unit and an adder/subtracter for forming the decode signal by combining the delayed receive signal and the non-delayed receive signal, the delayed signal having a delay substantially equal to a signal encoding time lag.

By signal encoding time lag is understood a time lag δ which corresponds to the advance or possibly to the delay of the individual pulses and which encodes the information carried by the signal. The delay introduced by the second delay unit is equal to, or close to the lag value δ. This value is known for a given type of encoding and is substantially constant. The lag value δ is of the order of about a hundred picoseconds, for example.

Forming a decode signal by subtracting the delayed receive signal from the receive signal allows the decode signal to be made dissymmetrical and thus authorises a distinction between advance pulses and delayed pulses.

As mentioned above, the invention also relates to a receiver, and particularly a radio receiver, provided with a demodulator as indicated above. The receiver may additionally comprises an aerial, an aerial amplifier and a unit for shaping the demodulated signal provided at the correlator output.

The invention finally relates to a process for demodulating a pulse-position modulated signal, wherein a decode signal is formed from the modulated receive signal, and wherein a correlation is made between the decode signal and the delayed receive signal.

Other characteristics and advantages of the invention will emerge from the description which follows, with reference to the figures in the appended drawings. This description is given purely by way of example and is not restrictive.

### BRIEF DESCRIPTION OF THE FIGURES

FIG. 1, already described, is a basic diagrammatic representation of a pulse-position modulated signal receiver, illustrating the prior art.

FIG. 2 is a basic diagrammatic representation of a pulse-position modulated signal receiver, in accordance with the invention,

FIG. 3 is a simplified diagram showing a particular embodiment of a demodulator that can be used in a receiver in accordance with FIG. 2,

FIG. 4 is a timing diagram showing a possible operation of a demodulator in accordance with FIG. 3,

FIG. 5 is a timing diagram showing another possible operation of the demodulator.

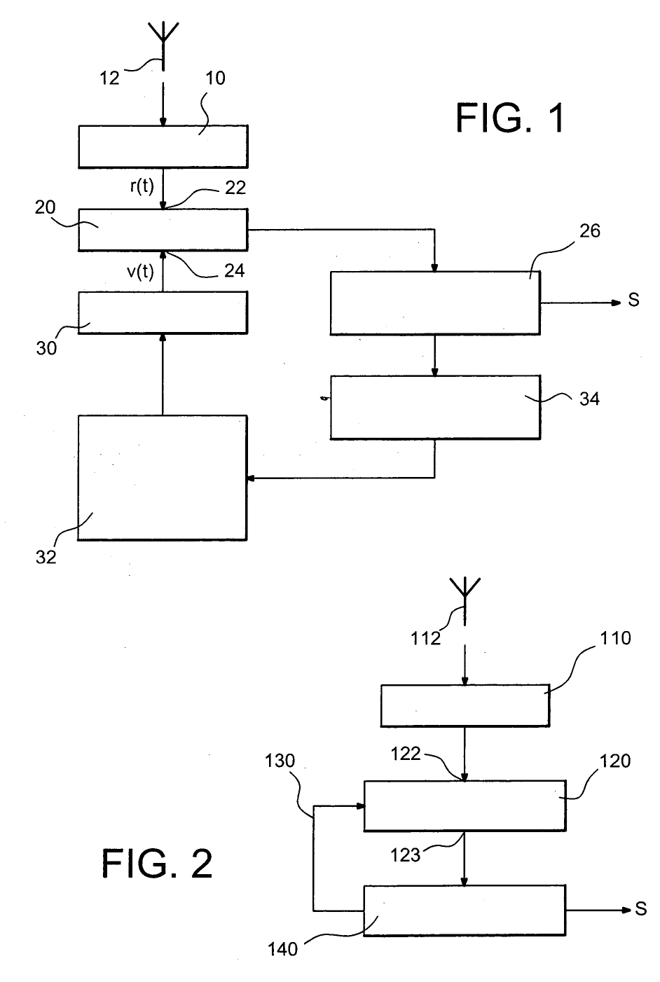

### DETAILED DESCRIPTION OF MODES OF IMPLEMENTATION OF THE INVENTION

In the following description, identical, similar or equivalent parts of the different figures are identified using the same reference symbols so as to facilitate cross-referral between the figures.

The pulse-position modulated signal receiver in FIG. 2 comprises an aerial 112, an aerial amplifier 110, a demodulator 120, and a signal-shaping unit 140. The demodulator is in the main just an auto-correlator. It lacks autonomous means for forming a local decode signal. The signal r(t) delivered at the amplifier output is applied to a demodulator input 122. The receive signal is directly used by the demodulator as an information carrying signal and as a basis for forming a decode signal. The demodulator output 123 delivers a demodulated signal. This signal may be exploited directly or, as is shown in FIG. 2, be directed towards the signal-shaping unit 140. This unit can be, for example, an electronic, analogue or digital circuit allowing the signal to be shaped into logic pulses. In a more straightforward way, the unit 140 may be just a low-pass integrating filter.

The reference 130 denotes a delay-locked loop allowing an optimised operation of the demodulator.

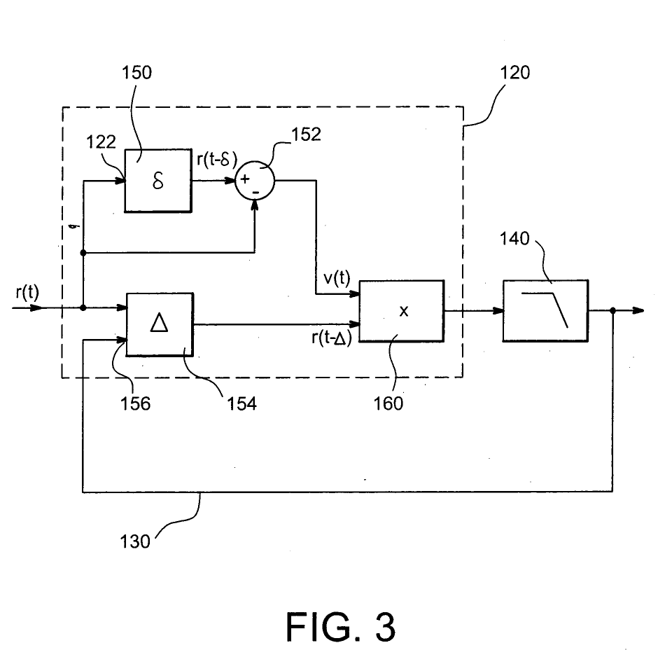

FIG. 3 shows in a more detailed way one potential embodiment of the demodulator 120.

One section of the demodulator comprises a first delay unit 154 which also receives the receive signal r(t). The first delay unit assigns the modulated receive signal a delay Δ equal to, or close to a mean pulse repetition time. It is equal, for example to 100 ns. The first delay unit provides a signal of the shape r(t−Δ).

The demodulator comprises another section for the formation of a decode signal v(t) from the receive signal r(t) applied to the input 122. The section comprises a second delay unit 150 capable of assigning the receive signal r(t) a delay δ. The delay δ is for example between one tenth of a nanosecond and one nanosecond. It is corrected so as to be equal to, or close to the signal pulse encoding time lag. The delayed signal is applied to an input of an adder/subtracter 152. The adder/subtracter 152 furthermore receives the non-delayed receive signal to combine it with the delayed signal. In the example shown, the combination is a simple subtraction of the delayed signal from the non-delayed signal. In this way a nonsymmetrical decode signal is obtained of the type v(t)=r(t−δ)−r(t). The variable t indicates simply the time dependence of the signal.

The decode signal and the delayed modulated signal coming from the first delay unit are supplied to a multiplier 160. The multiplier, which constitutes the heart of the auto-correlator, provides a product of the input signals. This product is nil when in particular one of the signals is nil at a given time t. This probability is related to the duty factor of the normally received signal, which is very low. This product may also be close to zero, on average, in the case of non-nil signals that have no correlation properties. This characteristic means that extraneous noise or competing signals can be very easily cut out.

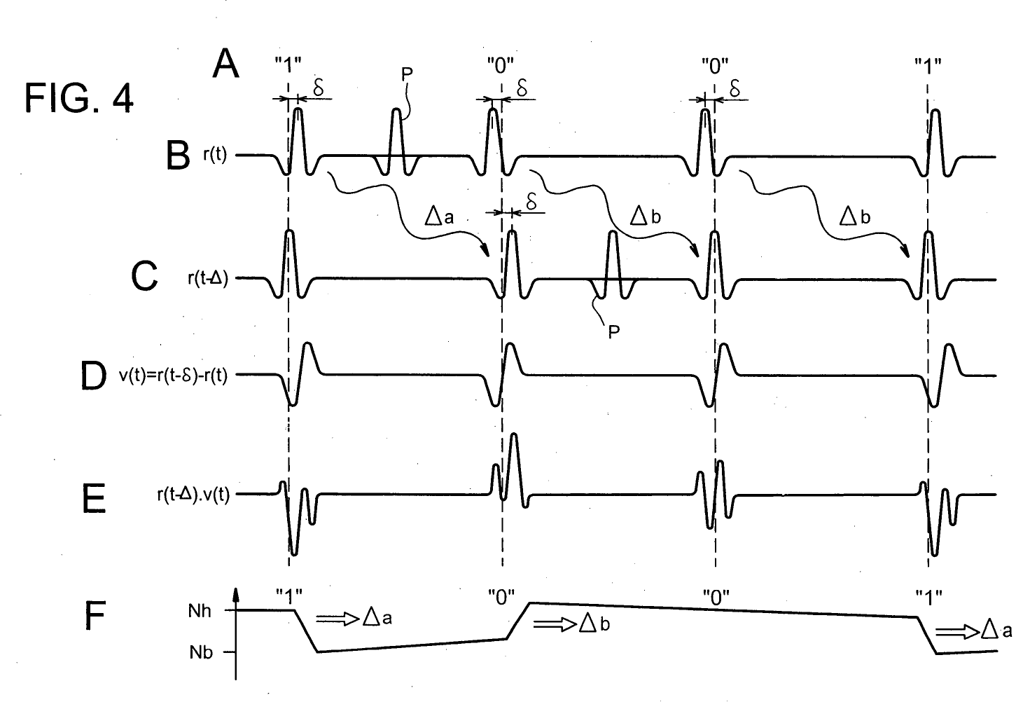

When the signals v(t) and r(t−Δ) are simultaneously non-nil, the multiplier delivers a pulse. In a particular operation, described below with reference to FIG. 4, the pulse delivered by the multiplier is either positive, or negative, or nil, on average. The pulse sign is dictated by the fact that the pulses of the decode signal v(t) are early, delayed, or synchronised with those of the delayed modulated signal r(t−Δ).

The sign of the pulses delivered by the multiplier therefore already constitutes a demodulated signal. The signal available at the auto-correlator output may be put into a more usual logic pulse shape with a succession of high and low states. This conversion is very easily achieved, in the example shown, via a low-pass filter 140. The integration constant of this filter is selected preferably above Δ.

The demodulated signal, available at the output of the filter 140 is the output signal. It may be directed for example towards various reproduction devices, such as sound reproduction devices, depending on the destination of the demodulator.

FIG. 3 shows that the second delay unit 154 has a corrective input 156. This input may to advantage be used to fine-tune the delay Δ. An accurate correction of the value of Δ allows the demodulator to be finely adapted for the demodulation of signals with very short pulses and allows good suppression of interference.

Delay correction is provided by a delay-locked loop 130, which connects the output of the low-pass filter 140 to the corrective input 156.

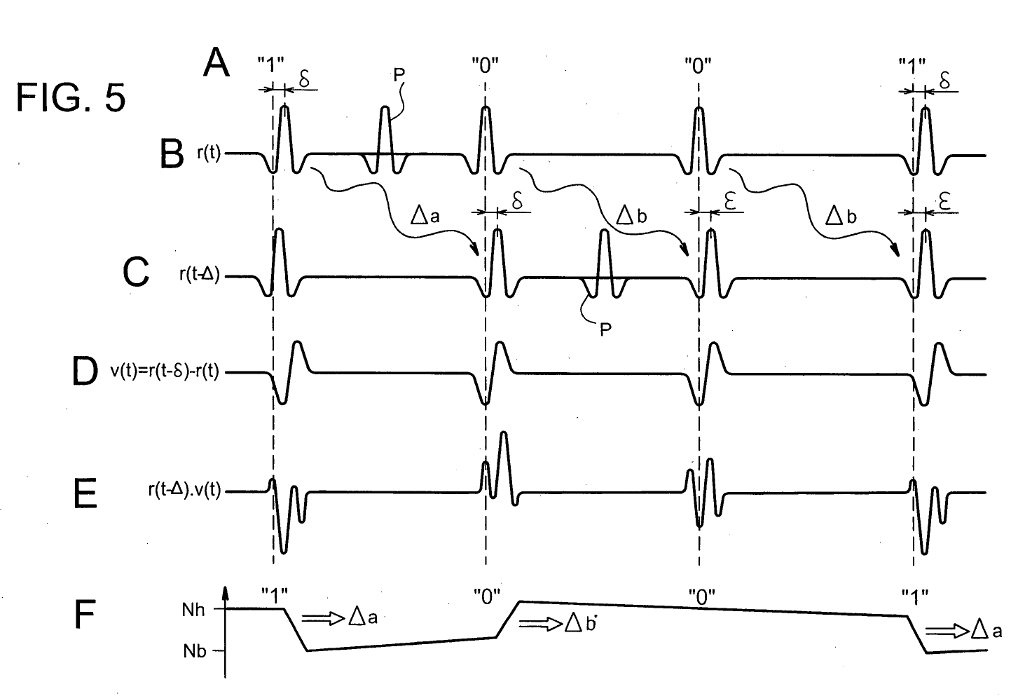

The operation of a demodulator as described above appears more clearly with reference to FIGS. 4 and 5 described below.

FIG. 4 corresponds to the demodulation of a signal for which the pulses encoding a first logic value (1) are assigned a positive time lag +δ and the pulses encoding a second logic value (0) are assigned a negative time lag −δ.

A first line A in FIG. 4 indicates the logic values corresponding to different successive pulses under consideration. These values are 1, 0, 0, and 1.

The line B shows the pulses of the receive signal r(t). The pulse lags +δ and −δ can be seen relative to their “normal” occurrence, which is indicated by broken lines. The time interval separating two normal pulse occurrences is the mean pulse repetition time, already mentioned at length.

The reference P indicates an interference pulse which is not in phase with the receive signal pulses.

The line C shows the pulses of the delayed signal r(t−Δ) coming from the second delay unit (154 in FIG. 3). It can be seen that the delay Δ is not always exactly the same for all the pulses. It is subject to very small variations while remaining equal or close to the mean pulse repetition time Δ₀. In the example shown, the delay Δ may assume two values between A₀−δ and Δ₀+δ. In the example in the figure the two values are: Δₐ=Δ₀ and Δ_{b}=Δ₀+δ.

Because of the very small duration of the encoding time lag considering the mean pulse repetition time, it may be considered as an initial estimate that the delay Δ is equal to Δ₀.

Arrows between lines B and C indicate, in the example shown, which of the values Δₐ and Δ_{b} are accepted in each case in order to form the delayed signal r(t−Δ). It may be observed that the interference pulse P is here also subject to a lag.

The line D shows the decode signal v(t) available at the output of the adder/subtracter 152. For reasons of simplification the interference pulses are not shown on line D in FIG. 4.

Finally, the line E shows the product r(t−Δ)×v(t) supplied by the multiplier 160.

By comparing the line A with the line E, it can be seen that the transition from an encoded data item 1 to an encoded data item 0 is expressed as a positive pulse at the multiplier output, and the transition from an encoded data item 0 to an encoded data item 1 is expressed as a negative pulse at the multiplier output. The absence of transition, in other words the preservation of a logic state 0 or 1 from one pulse to the next is expressed as a pulse of mean value close to 0 at the multiplier output. This appears for the third pulse of the signal given as an example in FIG. 4. It can be seen that multiplication causes the interference pulses, which are multiplied by 0, to disappear in every case where they do not exactly coincide with a signal pulse.

The last line F in FIG. 4 shows the signal shaped by the low-pass filter 140 provided downstream of the multiplier 160. The low-pass filter acts here as an integrator. A negative signal pulse at the multiplier output is expressed as a low output level Nb. Conversely, a positive signal pulse at the multiplier output is expressed as a high output level Nh. The effect of a pulse of nil mean value is to maintain the low or high level previously obtained.

The delay-locked loop 164 described with reference to FIG. 3 allows the high or low output states to be applied to the corrective input 156 of the second delay unit 154. The unit, in this implementation example, is designed to apply a delay Δₐ to the receive signal when the level applied to its corrective input is the low level and to apply the delay Δ_{b} to the receive signal when the level applied to its corrective input is the high level. Moving from Δₐ to Δ_{b} comes down simply to adding a value δ to or deducting it from the delay.

FIG. 5 shows another possible operation of the demodulator for a signal that has a different logic coding. The coding is based on the fact that a first logic state (0) is expressed as a nil lag of the pulses relative to their normal occurrence time position and that a second logic state (1) is expressed as a lag +δ of the pulses relative to their normal occurrence time position.

The different parts A to F in FIG. 5 correspond to the same types of signals as those shown in FIG. 4, with the result that they can be compared with them in twos.

In the example relating to FIG. 5, the second delay unit assigns the receive signal r(t) a delay Δ between two extreme limits. These limits are Δₐ=Δ₀, in other words the mean pulse repetition time, and Δ_{b}=Δ₀+δ. More exactly, the delay Δ may assume two values which are Δ₀ and A₀+ε where ε is a duration less than or equal to the encoding time lag δ.

Arrows indicate in FIG. 5 which of the delays Δₐ or Δ_{b} respectively is being taken into account.

The parts D, E, and F in FIG. 5 are not fundamentally different from the same parts in FIG. 4. Reference may therefore be made to the preceding figure.

### DOCUMENTS CITED

(1) “IMPULSE RADIO”, IEEE PIMRC'97, Helsinki Finland, 1997, pp 245-267, by Robert A. Scholtz and Moe Z. Win

1. Pulse-position modulated signal demodulator comprising a correlator, characterised in that the correlator is an auto-correlator (150, 152, 154, 160) provided with means (150, 152) for generating a decode signal from a pulse-position modulated receive signal.

2. Demodulator according to claim 1, comprising a first delay unit (154) for forming a first delayed receive signal (r(t−Δ) from the receive signal (r(t)) and a multiplier (160) for multiplying the first delayed receive signal by the decode signal, the first delayed receive signal being assigned a delay (Δ) substantially equal to a mean pulse repetition time or a multiple of this mean time.

3. Demodulator according to claim 2, wherein the means for generating a decode signal are able to provide a decode signal (v(t)) such that its multiplication by the first delayed receive signal (r(t−Δ) gives a signal carrying at least two information items about the identity or the non-identity of two successive pulses.

4. Demodulator according to claim 3, wherein the means for generating a decode signal comprise a second delay unit (150) and an adder/subtracter (152) for forming a decode signal by combining the delayed receive signal (r(t−δ) and the non-delayed receive signal (r(t)), the delayed signal having a delay (δ) substantially equal to a signal encoding time lag.

5. Demodulator according to claim 3, wherein the means for generating a decode signal comprise an integrator.

6. Pulse-position modulated signal receiver according to claim 1, comprising a demodulator.

7. Receiver according to claim 6, additionally comprising a unit for shaping the demodulated signal connected to a demodulator output.

8. Pulse-position modulated signal receiver comprising a demodulator in accordance with claim 2 and comprising a delay-locked loop (130) associated with the first delay unit (154) of the demodulator.

9. Receiver according to claim 8, wherein the delay-locked loop is connected between a low-pass filter connected to the demodulator output and a corrective input (156) of the second delay unit (154).

10. Process for demodulating a pulse-position modulated signal, characterised in that a decode signal v(t)) is formed from the modulated receive signal, and in that a correlation is made between the decode signal and the delayed receive signal.

11. Process according to claim 10, wherein the decode signal is multiplied by the receive signal assigned a delay (Δ) substantially equal to a mean pulse repetition time.

12. Process according to claim 11, wherein the delay (Δ) is corrected in a delay-locked loop, as a function of a demodulated signal.

13. Process according to claim 10, wherein the decode signal is formed by subtracting a delayed receive signal from the non-delayed receive signal.

14. Process according to claim 10, wherein the delayed receive signal is formed by assigning to the receive signal a first delay substantially equal to a signal encoding time lag (δ).

15. Process according to claim 10, wherein the decode signal is formed by integrating the receive signal.
